(19) United States
(12) Patent Application Publication
(10) Pub. No.: US 2023/0091288 A1
(43) Pub. Date: Mar. 23, 2023

(54) Electroluminescent Device and Display Apparatus

(71) Applicant: BOE Technology Group Co., Ltd., Beijing (CN)

(72) Inventor: Dan WANG, Beijing (CN)

(21) Appl. No.: 17/612,570

(22) PCT Filed: Feb. 5, 2021
(86) PCT No.: PCT/CN2021/075392

§ 371 Date: Nov. 19, 2021

(51) Int. Cl. H01L 51/00; C09K 11/02

(52) U.S. Cl. CPC H01L 51/0058; C09K 11/02; H01L 51/5012

(57) ABSTRACT

Provided is an electroluminescent device, including an anode, a cathode, and a light emitting layer disposed between the anode and the cathode, wherein the light emitting layer includes a host material and a dopant material; the host material includes a component A and a component B;
the component A and the component B have the following general structural formula:

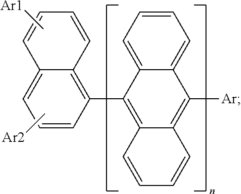

wherein n is a positive integer greater than or equal to 1; and Ar is any one of the following structures:

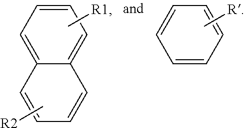

### CROSS-REFERENCE TO RELATED APPLICATION

The present application is a U.S. National Phase Entry of International Application No. PCT/CN2021/075392 having an international filing date of Feb. 5, 2021, the content of which is hereby incorporated by reference.

### TECHNICAL FIELD

The embodiments of the present disclosure relate to, but are not limited to, the field of display technologies, in particular to an electroluminescent device and a display apparatus.

### BACKGROUND

The Organic Light Emitting Diode (OLED) display apparatus has many advantages, such as all solid state, active light emission, fast response speed, high contrast, no visual angle limitation, and flexible display, and is a new display technology developed in the mid-20th century and widely used in daily production and life of people. The Liquid Crystal Display (LCD) is the mainstream flat panel display at present, and in particular, the response speed, brightness, and contrast thereof and the light-weight of the display are greatly improved after the LCD is combined with the thin film transistor technology. However, an LCD panel cannot emit light by itself, and a backlight source is required to illuminate the panel for light emission, causing certain limitations and impossibility of achieving improvement. Due to the superior performance and huge market potential, the OLED display apparatus attracts many manufacturers and scientific research institutions all over the world to invest in the production and development of the OLED display apparatus.

In the red, green and blue (RGB) light emitting systems of the OLED display apparatuses, the host material of the light emitting layers of some red OLED devices and green OLED devices is a premix material, that is, an electron material and a hole material form an exciplex host material by means of coaction, and the dopant material of the light emitting layer is excited by means of energy transfer to achieve light emission. However, most of the blue light emitting systems use a single-component fluorescent host material. The energy level and mobility of the single-component host material are unadjustable, limiting the selection range of the material of the blue light OLED device and the improvement of device performance and thus limiting the adjustment range of the process in mass production.

### SUMMARY

The following is a brief description of the subject matter detailed herein. This brief description is not intended to limit the scope of protection of the claims.

An embodiment of the present disclosure provides an electroluminescent device, including an anode, a cathode, and a light emitting layer disposed between the anode and the cathode, wherein the light emitting layer includes a host material and a dopant material; the host material includes a component A and a component B;

the component A and the component B have the following general structural formula:

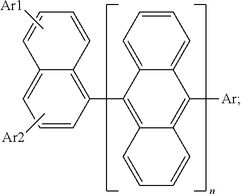

wherein n is a positive integer greater than or equal to 1;

Ar is any one of the following structures:

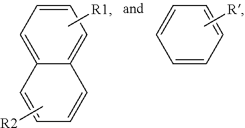

wherein R1, R2, and R′ are independently selected from a hydrogen atom, a halogen atom, a cyano group, a substituted or unsubstituted alkyl group, a substituted or unsubstituted alkenyl group, a substituted or unsubstituted alkynyl group, a substituted or unsubstituted alkoxy group, a substituted or unsubstituted aryl group, a substituted or unsubstituted amino group, and a substituted or unsubstituted heterocyclic group; and

Ar1 and Ar2 are independently selected from a hydrogen atom, a halogen atom, a cyano group, substituted or unsubstituted alkyl group, a substituted or unsubstituted alkenyl group, a substituted or unsubstituted alkynyl group, a substituted or unsubstituted alkoxy group, a substituted or unsubstituted aryl group, a substituted or unsubstituted amino group, and a substituted or unsubstituted heterocyclic group.

Optionally, the component A and the component B are isomers of each other.

Optionally, a ratio of a mass of the component A to a total mass of the component A and the component B is a, 1%≤a<100%; and the component A and the component B satisfy: |HOMO_{A-host}|≤|HOMO_{B-host}|, wherein HOMO_{A-host} is a highest occupied molecular orbital energy level of the component A, and HOMO_{B-host} is a highest occupied molecular orbital energy level of the component B.

Optionally, the dopant material, the component A, and the component B satisfy: HOMO_{dopant}|≤|HOMO_{A-host}|≤|HOMO_{B-host}|; wherein HOMO_{dopant} is a highest occupied molecular orbital energy level of the dopant material, HOMO_{A-host} is a highest occupied molecular orbital energy level of the component A, and HOMO_{B-host} is a highest occupied molecular orbital energy level of the component B.

Optionally, the electroluminescent device further includes an electron block layer disposed between the anode and the light emitting layer, and a material of the electron block layer, the component A, and the component B satisfy:

0<|HOMO_{A-host}−HOMO_{EBL}|≤0.3 eV, 0<|HOMO_{B-host}−HOMO_{EBL}|≤0.3 eV, and |HOMO_{EBL}|<|HOMO_{A-host}|≤|HOMO_{B-host}|;

wherein HOMO_{EBL} is a highest occupied molecular orbital energy level of the material of the electron block layer, HOMO_{A-host} is a highest occupied molecular orbital energy level of the component A, and HOMO_{B-host} is a highest occupied molecular orbital energy level of the component B.

Optionally, the host material consists of the component A and the component B.

Optionally, the component A has the following structural formula:

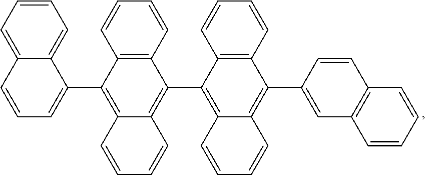 [SMILES: c1ccc2cc(-c3c4ccccc4c(-c4c5ccccc5c(-c5cccc6ccccc56)c5ccccc45)c4ccccc34)ccc2c1]

and

the component B has the following structural formula:

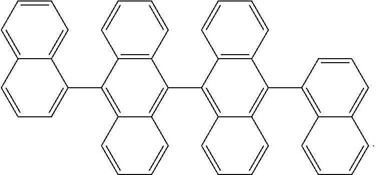 [SMILES: c1ccc2c(-c3c4ccccc4c(-c4c5ccccc5c(-c5cccc6ccccc56)c5ccccc45)c4ccccc34)cccc2c1]

Optionally, the component A has the following structural formula:

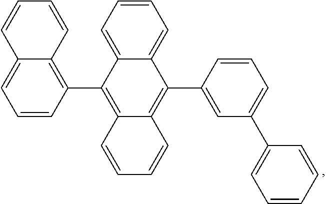 [SMILES: c1ccc(-c2cccc(-c3c4ccccc4c(-c4cccc5ccccc45)c4ccccc34)c2)cc1]

and

the component B has the following structural formula:

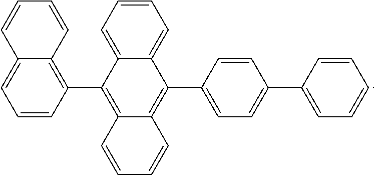 [SMILES: c1ccc(-c2ccc(-c3c4ccccc4c(-c4cccc5ccccc45)c4ccccc34)cc2)cc1]

Optionally, the component A has the following structural formula:

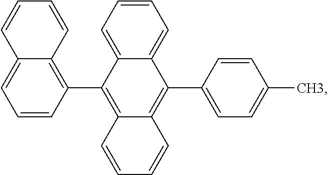 [SMILES: Cc1ccc(-c2c3ccccc3c(-c3cccc4ccccc34)c3ccccc23)cc1]

and

the component B has the following structural formula:

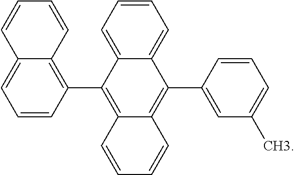 [SMILES: Cc1cccc(-c2c3ccccc3c(-c3cccc4ccccc34)c3ccccc23)c1]

Optionally, the electroluminescent device further includes a hole injection layer, a hole transport layer, and an electron block layer sequentially stacked between the anode and the light emitting layer, and a hole block layer, an electron transport layer, and an electron injection layer sequentially stacked between the light emitting layer and the cathode.

An embodiment of the present disclosure further provides a display apparatus, including the electroluminescent device according to any one of the embodiments.

After reading and understanding of the drawings and the detailed description, other aspects can be understood.

### BRIEF DESCRIPTION OF DRAWINGS

The drawings are used to provide a further understanding of the technical solutions of the present disclosure and constitute a portion of the description, and are used together with the embodiments of the present disclosure to explain the technical solutions of the present disclosure without limiting the technical solutions of the present disclosure. The shape and size of the components in the drawings do not reflect the actual scale, and are merely intended to describe the content of the present disclosure.

FIG. 1 is a schematic diagram of a planar structure of a display region of a display substrate.

FIG. 2 is a schematic diagram of a local sectional structure of the display substrate in FIG. 1.

FIG. 3 is a schematic diagram of a structure of an electroluminescent device according to an exemplary embodiment of the present disclosure.

### DETAILED DESCRIPTION

The embodiments herein may be implemented in a number of different forms. It is very easy for those skilled in the art to understand the fact that the embodiments and content may be changed into various forms without departing from the purpose and scope of the present disclosure. Therefore, the present disclosure should not be interpreted as being limited to the contents recorded in the following embodiments. Without conflict, the embodiments in the present disclosure and the features in the embodiments may be randomly combined with each other.

In the drawings, sometimes for clarity, the size of a constituent element, the thickness of a layer, or an area may be exaggerated. Therefore, any embodiment of the present disclosure is not necessarily limited to the dimensions illustrated in the drawings, and the shape and size of the components in the drawings do not reflect the actual scale. In addition, the drawings schematically illustrate ideal examples, and any embodiment of the present disclosure is not limited to the shape, numerical value, or the like illustrated in the drawings.

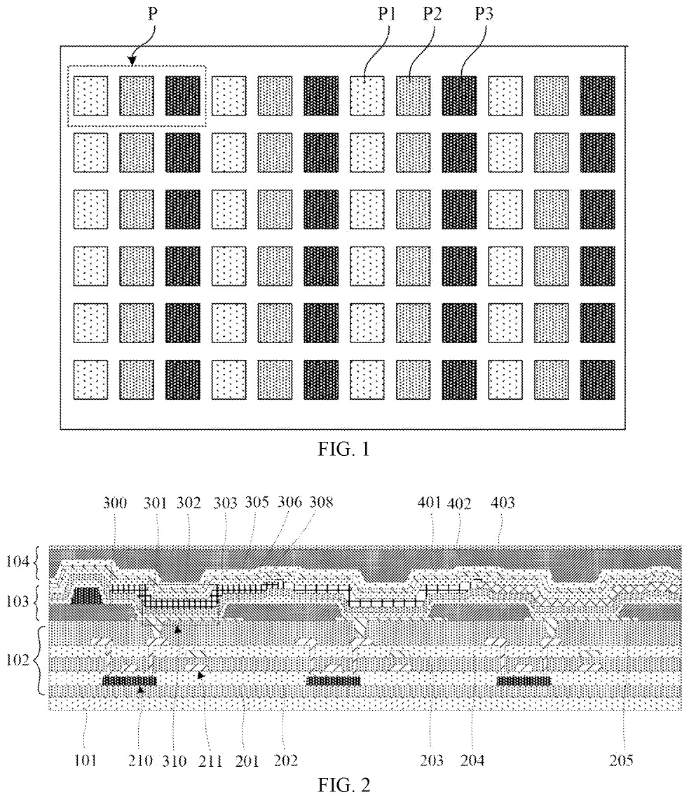

FIG. 1 is a schematic diagram of a planar structure of a display region of a display substrate. Referring to FIG. 1, the display region may include a plurality of pixel units P arranged in an array. At least one of the plurality of pixel units P includes a first sub-pixel P1 emitting first color light, a second sub-pixel P2 emitting second color light, and a third sub-pixel P3 emitting third color light. Each of the first sub-pixel P1, the second sub-pixel P2, and the third sub-pixel P3 includes a light emitting device and a pixel drive circuit driving the light emitting device to emit light. The first sub-pixel P1, the second sub-pixel P2, and the third sub-pixel P3 may be configured to emit red light, green light, and blue light respectively. The pixel unit P may further include sub-pixels emitting light of other colors, such as a sub-pixel emitting white light. The shape of the sub-pixel in the pixel unit may be a rectangle, a rhombus, a pentagon, or a hexagon, etc. When the pixel unit includes three sub-pixels, the three sub-pixels may be arranged in a row, a column, or a “ [symbol] ” shape; and when the pixel unit includes four sub-pixels, the four sub-pixels may be arranged in a row, a column, or a square, which is not limited in the present disclosure.

FIG. 2 is a schematic diagram of a sectional structure of the display region of the display substrate, and illustrates a structure of three sub-pixels of an OLED display substrate. Referring to FIG. 2, on a plane perpendicular to the display substrate, the display substrate may include a drive circuit layer 102 disposed on a substrate 101, a light emitting structure layer 103 disposed on a side of the drive circuit layer 102 away from the substrate 101, and an encapsulation structure layer 104 disposed on a side of the light emitting structure layer 103 away from the substrate 101. The drive circuit layer 102 includes a pixel drive circuit. The light emitting structure layer 103 includes a plurality of OLED light emitting devices 310, and each OLED light emitting device 310 is connected to a corresponding pixel drive circuit. In some possible embodiments, the display substrate may include other film layers, such as a column spacer, which is not limited in the present disclosure.

In some exemplary embodiments, the substrate 101 may be a flexible substrate or may be a rigid substrate. The flexible substrate may include a first flexible material layer, a first inorganic material layer, a semiconductor layer, a second flexible material layer, and a second inorganic material layer. The material of the first flexible material layer and the second flexible material layer may be polyimide (PI), polyethylene terephthalate (PET), or polymer soft film subjected to surface treatment. The material of first inorganic material layer and the second inorganic material layer may be silicon nitride (SiNx) or silicon oxide (SiOx) used to improve the water-oxygen resistance of the substrate. The material of the semiconductor layer may be amorphous silicon (a-si).

In some exemplary embodiments, as illustrated in FIG. 2, the drive circuit layer 102 of each sub-pixel may include a plurality of transistors and storage capacitors forming the pixel drive circuit. FIG. 2 is illustrated by taking each sub-pixel including one drive transistor and one storage capacitor as an example. In some possible embodiments, the drive circuit layer 102 of each sub-pixel may include: a first insulating layer 201 disposed on the substrate 101; an active layer disposed on the first insulating layer 201; a second insulating layer 202 covering the active layer; a gate electrode and a first capacitor electrode disposed on the second insulating layer 202; a third insulating layer 203 covering the gate electrode and the first capacitor electrode; a second capacitor electrode disposed on the third insulating layer 203; a fourth insulating layer 204 covering the second capacitor electrode, wherein the second insulating layer 202, the third insulating layer 203, and the fourth insulating layer 204 are provided with vias, and the vias expose the active layer; a source electrode and a drain electrode disposed on the fourth insulating layer 204, wherein the source electrode and the drain electrode are separately connected to the active layer by means of the vias; and a planarization layer 205 covering the above-mentioned structure, wherein the planarization layer 205 is provided with a via, and the via exposes the drain electrode. The active layer, the gate electrode, the source electrode, and the drain electrode form a drive transistor 210, and the first capacitor electrode and the second capacitor electrode form a storage capacitor 211.

In some exemplary embodiments, referring to FIG. 2, the light emitting structure layer 103 may include an anode 301, a pixel definition layer 300, a cathode 303, and an organic functional layer between the anode 301 and the cathode 303. The organic functional layer at least includes a light emitting layer 302. The anode 301 is disposed on the planarization layer 205 and is connected to the drain electrode of the drive transistor 210 by means of a via provided in the planarization layer 205; the pixel definition layer 300 is disposed on the anode 301 and the planarization layer 205, the pixel definition layer 300 is provided with a pixel opening, and the pixel opening exposes the anode 301. In some examples, the light emitting layer 302 is at least partially disposed within the pixel opening and is connected to the anode 301; the cathode 303 is disposed on the light emitting layer 302 and is connected to the light emitting layer 302. In other examples, the organic functional layer may further include a hole injection layer, a hole transport layer 305, and an electron block layer 306 located between the anode 301 and the light emitting layer 302 and sequentially stacked on the anode 301, and a hole block layer, an electron transport layer 308, and an electron injection layer located between the light emitting layer 302 and the cathode 303 and sequentially stacked on the light emitting layer 302. The anode 301, the organic functional layer, and the cathode 303 of each sub-pixel form an OLED light emitting device 310 which is configured to emit light of a corresponding color under the drive of the corresponding pixel drive circuit. In some examples, the light emitting layer 302 of each sub-pixel is located within a sub-pixel region in which the sub-pixel is located, and the edges of the light emitting layers of adjacent sub-pixels may overlap or be isolated from each other. In the organic functional layers of all the sub-pixels, any other film layer except the light emitting layer may be an integrated connecting film layer covering all the sub-pixels, and may be referred to as a common connecting layer.

In some exemplary embodiments, the encapsulation structure layer 104 may include a first encapsulation layer 401, a second encapsulation layer 402, and a third encapsulation layer 403 which are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403, thus ensuring that no external water vapor enters the light emitting device 310.

In some exemplary embodiments, a display substrate including OLED devices may be manufactured by means of the following manufacturing method. First, a drive circuit layer is formed on a substrate by means of a patterning process, wherein the drive circuit layer of each sub-pixel may include a drive transistor and a storage capacitor forming the pixel drive circuit. Then, a planarization layer is formed on the substrate on which the above structure is formed, and a via exposing a drain electrode of the drive transistor is formed in the planarization layer of each sub-pixel. After that, an anode is formed on the substrate on which the above structure is formed by means of a patterning process, wherein the anode of each sub-pixel is connected to the drain electrode of the drive transistor by means of the via in the planarization layer. Next, a pixel definition layer is formed on the substrate on which the above structure is formed by means of a patterning process, and a pixel opening exposing the anode is formed on the pixel definition layer of each sub-pixel, wherein each pixel opening serves as a light emitting region of each sub-pixel. Then, a hole injection layer and a hole transport layer are sequentially formed on the substrate on which the above structure is formed by means of evaporation using an open mask, wherein the hole injection layer and the hole transport layer are the common connecting layer, that is, the hole injection layers of all the sub-pixels are integrated into a whole and the hole transport layers of all the sub-pixels are integrated into a whole; and the hole injection layer and the hole transport layer have approximately same area, but different thicknesses. After that, an electron block layer and a red light emitting layer, an electron block layer and a green light emitting layer, and an electron block layer and a blue light emitting layer are respectively formed at different sub-pixels by means of evaporation using a fine metal mask, wherein the electron block layers and the light emitting layers of adjacent sub-pixels may overlap or be isolated from each other. Then, a hole block layer, an electron transport layer, an electron injection layer, and a cathode are sequentially formed by means of evaporation using an open mask, wherein the hole block layer, the electron transport layer, the electron injection layer, and the cathode are all the common connecting layer, that is, the hole block layers of all the sub-pixels are integrated into a whole, the electron transport layers of all the sub-pixels are integrated into a whole, the electron injection layers of all the sub-pixels are integrated into a whole, and the cathodes of all the sub-pixels are integrated into a whole.

In some exemplary embodiments, the evaporation of the light emitting layer may adopt a multi-source co-evaporation mode to form the light emitting layer including a host material and a dopant material, and the doping concentration of the dopant material may be regulated by controlling an evaporation rate of the dopant material in the evaporation process, or the doping concentration of the dopant material may be regulated by controlling a ratio between the evaporation rate of the host material and the evaporation rate of the dopant material.

In the OLED light emitting devices, a host material of light emitting layers of some red OLED devices and green OLED devices is a premix material, that is, an electron material and a hole material form an exciplex host material by means of coaction, and the dopant material of the light emitting layer is excited by means of energy transfer to achieve light emission. The advantage of two-component doping in the host material of the light emitting layer is that the overall energy level and mobility of the host material can be adjusted by adjusting the energy level and mobility of different components, providing a larger space for the selection of the OLED device material and the improvement of the device performance. However, for a host material of a light emitting layer of a blue OLED device, since an energy gap for light emission is extremely large, the requirement on an energy level difference (an energy level difference between the highest occupied molecular orbital level HOMO and the lowest unoccupied molecular orbital level LUMO) of the host material is relatively high, which is difficult to be realized by means of an exciplex. Therefore, at present, most of the blue light emitting systems use a single-component fluorescent host material, and the unadjustable energy level and mobility of the single-component host material limit the selection range of the material of the blue light OLED device and the improvement of the device performance and limits the adjustment range of the process in mass production.

An embodiment of the present disclosure provides an electroluminescent device, including an anode, a cathode, and a light emitting layer disposed between the anode and the cathode. The light emitting layer includes a host material and a dopant material, and the host material includes a component A and a component B.

The component A and the component B have the following general structural formula:

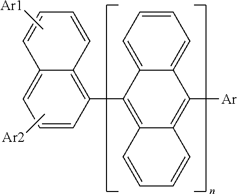

wherein n is a positive integer greater than or equal to 1;

Ar is any one of the following structures:

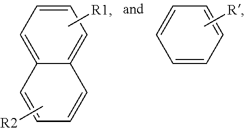

wherein R1, R2, and R′ are independently selected from a hydrogen atom, a halogen atom, a cyano group, a substituted or unsubstituted alkyl group, a substituted or unsubstituted alkenyl group, a substituted or unsubstituted alkynyl group, a substituted or unsubstituted alkoxy group, a substituted or unsubstituted aryl group, a substituted or unsubstituted amino group, and a substituted or unsubstituted heterocyclic group;

Ar1 and Ar2 are independently selected from a hydrogen atom, a halogen atom, a cyano group, a substituted or unsubstituted alkyl group, a substituted or unsubstituted alkenyl group, a substituted or unsubstituted alkynyl group, a substituted or unsubstituted alkoxy group, a substituted or unsubstituted aryl group, a substituted or unsubstituted amino group, and a substituted or unsubstituted heterocyclic group.

In the electroluminescent device provided by the embodiment of the present disclosure, two materials both satisfying the above general formula are mixed as the host material of the light emitting layer. Such a material system enables the energy level and carrier mobility of the host material to be adjustable, thus realizing better matching and combination of the energy level and carrier mobility with the materials of other film layers in the device, enlarging the selection range of the materials of the other film layers in the device, and facilitating the improvement of the device performance. In addition, due to the existence of intermolecular acting force, an ordered arrangement of molecules of a single-component host material is easy to be formed, resulting in crystallization. In an embodiment of the present disclosure, the component A and the component B are introduced into the host material of the light emitting layer. Since molecular crystallization properties of the component A and the component B are different, and a material system difficult to be crystallized can be formed under the intermolecular interaction, the problem of hole plugging at the position of an evaporation source caused by the strong crystallization property of the single-component host material in the production process may be avoided. Therefore, the technical effects of optimizing the light emitting characteristics and mass production of the device may be achieved.

In some exemplary embodiments, the component A and the component B may be isomers of each other. In this example, the component A and the component B may have the same structural formula and have the same molecular molar mass.

In some exemplary embodiments, in the light emitting layer, a ratio of a mass of the component A to a total mass of the component A and the component B is a, 1%≤a<100%; and a molecular molar mass of the component A is equal to a molecular molar mass of the component B. The component A and the component B satisfy: |HOMO_{A-host}|≤HOMO_{B-host}|, wherein HOMO_{A-host} is a highest occupied molecular orbital energy level of the component A, and HOMO_{B-host} is a highest occupied molecular orbital energy level of the component B.

In this example, the component A and the component B satisfy the above ratio and energy level relationship, thus forming a hole injection gradient in the light emitting layer, which facilitates hole transport.

In some exemplary embodiments, the dopant material, the component A, and the component B satisfy:

|HOMO_{dopant}|≤|HOMO_{A-host}|≤|HOMO_{B-host}|;

where, HOMO_{dopant} is the highest occupied molecular orbital energy level of the dopant material, HOMO_{A-host} is the highest occupied molecular orbital energy level of the component A, and HOMO_{B-host} is the highest occupied molecular orbital energy level of the component B.

In this example, the dopant material, the component A, and the component B satisfy the above energy level relationship, so that when a hole is transported from the host material to the dopant material, it benefits the dopant material to capture the hole, improving the hole transport capability and thereby facilitating the improvement of the luminous efficiency and service life of the device.

In some exemplary embodiments, the electroluminescent device may further include an electron block layer (EBL) disposed between the anode and the light emitting layer, and the material of the electron block layer, the component A, and the component B satisfy:

0<|HOMO_{A-host}−HOMO_{EBL}|≤0.3 eV, 0<|HOMO_{B-host}−HOMO_{EBL}|≤0.3 eV, and |HOMO_{EBL}|<|HOMO_{A-host}|≤|HOMO_{B-host}|;

where, HOMO_{EBL} is the highest occupied molecular orbital energy level of the material of the electron block layer, HOMO_{A-host} is the highest occupied molecular orbital energy level of the component A, and HOMO_{B-host} is the highest occupied molecular orbital energy level of the component B.

In this example, the material of the electron block layer, the component A, and the component B satisfy the above energy level relationship, which can improve the hole transport capability, facilitate hole transport from the electron block layer to the light emitting layer, reduce carrier accumulation at an interface between the electron block layer and the light emitting layer, and thereby facilitate the improvement of the luminous efficiency and service life of the device.

In some exemplary embodiments, the highest occupied molecular orbital energy level of the dopant material is −5.2 Ev to −5.8 eV, that is, the range of HOMO_{dopant} is −5.2 Ev to −5.8 eV. The highest occupied molecular orbital energy level of the material of the electron block layer is −5.4 Ev to −5.9 eV, that is, the range of HOMO_{EBL} is −5.4 Ev to −5.9 eV.

Herein, a relationship between the highest occupied molecular orbital (HOMO) energy levels of different materials refers to a relationship between the absolute values of the HOMO energy levels.

In some exemplary embodiments, the HOMO energy level relationship among the component A, the component B, the dopant material, and the material of the electron block layer is optimized, facilitating hole carrier transport from the anode to the light emitting layer, reducing the electron carrier accumulation at the interface between the electron block layer and the light emitting layer, reducing the damage caused by electrons to the electron block layer, and thereby improving the service life of the device.

In some exemplary embodiments, the host material of the light emitting layer may consist of the component A and the component B.

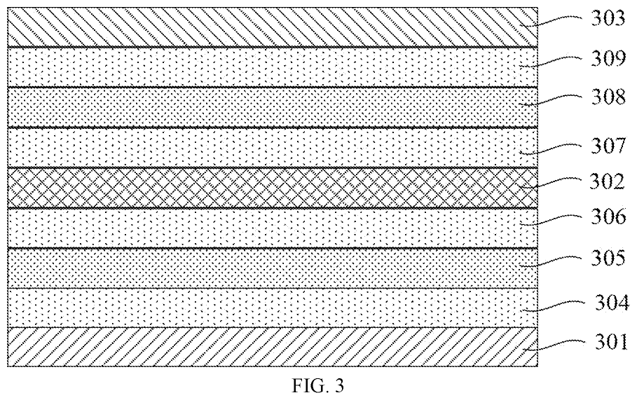

In some exemplary embodiments, referring to FIG. 3, the electroluminescent device may include a hole injection layer (HIL) 304, a hole transport layer (HTL) 305, and an electron block layer (EBL) 306 sequentially stacked between the anode 301 and the light emitting layer (EML) 302, and a hole block layer (HBL) 307, an electron transport layer (ETL) 308, and an electron injection layer (EIL) 309 sequentially stacked between the light emitting layer (EML) 302 and the cathode 303. In this example, the electroluminescent device may include any one or more film layers selected from the hole injection layer 304, the hole transport layer 305, the electron block layer 306, the hole block layer 307, the electron transport layer 308, and the electron injection layer 309. In an example of this embodiment, the structure of the organic functional layer (film layer between the anode and the cathode) of the electroluminescent device may be as follow: HIL/HTL/EBL/Host(A+B):Dopant/HBL/ETL/EIL. The hole transport layer 305 can increase the hole transport rate, reduce the hole injection barrier, and improve the hole injection efficiency. The electron block layer 306 can block electrons and excitons in the light emitting layer from migrating to a side where the anode is located, and thus improve the luminous efficiency. The hole block layer 307 can block holes and excitons in the light emitting layer from migrating to a side where the cathode is located, and thus improve the luminous efficiency. The electron transport layer 308 can increase the electron transport rate.

In some exemplary embodiments, the anode 301 may be made of a material with a high work function. For a bottom emission OLED, the anode 301 may be made of a transparent oxide material such as indium tin oxide (ITO) or indium zinc oxide (IZO). For a top emission OLED, the anode 301 may be made of a composite structure of metal and transparent oxide, such as Ag/ITO, Ag/IZO, or ITO/Ag/ITO.

In some exemplary embodiments, the cathode 303 may be made of a metal material and formed by means of an evaporation process, and the metal material may be magnesium (Mg), silver (Ag), or aluminum (Al), or an alloy material such as Mg:Ag alloy.

In some exemplary embodiments, the hole injection layer 304 may be a single-component film layer, and the material thereof may be 2,3,6,7,10,11-hexacyano-1,4,5,8,9,12-hexaazatriphenylene (HATCN), copper phthalocyanine (CuPc), or molybdenum trioxide (MoO₃). Alternatively, the hole injection layer 304 may be a doped film layer, and the material thereof may be a radialene or quinone compound doped with aromatic amine compound, such as 2,3,5,6-tetrafluoro-7,7′,8,8′-tetracyanodimethyl-p-benzoquinone (F₄TCNQ) doped with N,N′-bis(1-naphthyl)-N,N′-diphenyl-1,1′-biphenyl-4-4′-diamine (NPB), or F₄TCNQ doped with N-N′-diphenyl-N,N′-bis(3-methylphenyl)-1,1′-biphenyl-4,4′-diamine (TPD).

In some exemplary embodiments, the material of the hole transport layer 305 and the material of the electron block layer 306 may each include a hole transport material containing a group such as aniline, aromatic amine, carbazole, fluorine, or spirofluorene, for example, NPB and TPD.

In some exemplary embodiments, the material of the hole block layer 307 and the material of the electron transport layer 308 may each include an electron transport material containing a group such as triazine, imine, carbazole, or nitrile, for example, bis(2-methyl-8-quinolinyl)-4-(phenylphenol)aluminum (BAlq).

In some exemplary embodiments, the electron transport layer 308 may be a mixed film of an electron transport material and LiQ (lithium octahydroxyquinoline), and the electron transport material may be a nitrogen-containing heterocyclic compound such as 4,7-diphenyl-1,10-phenanthroline (Bphen), or 1,3,5-tris(1-phenyl-1H-benzimidazol-2-yl)benzene (TPBi).

In some exemplary embodiments, the electroluminescent device may be a blue electroluminescent device. The dopant material may be a blue fluorescent material, and the light emission wavelength of the dopant material ranges from 450 nm to 490 nm.

In some exemplary embodiments, the doping concentration of the dopant material may be 0.5% to 4%, for example, 1% to 3%. The doping concentration refers to a proportion of the dopant material in the light emitting layer 302, which may be a mass percentage. In the manufacturing of the light emitting layer, the host material and dopant material of the light emitting layer may be evaporated by means of a multi-source evaporation process at the same time, so that the host material and dopant material are evenly dispersed in the light emitting layer 302. The doping concentration may be regulated by controlling an evaporation rate of the dopant material in the evaporation process, or by controlling a ratio between the evaporation rate of the host material and the evaporation rate of the dopant material.

In some exemplary embodiments, the component A has the following structural formula:

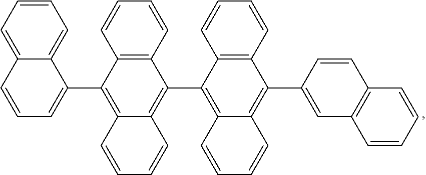 [SMILES: c1ccc2cc(-c3c4ccccc4c(-c4c5ccccc5c(-c5cccc6ccccc56)c5ccccc45)c4ccccc34)ccc2c1]

and the component B has the following structural formula:

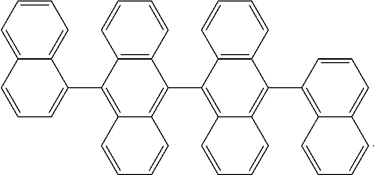 [SMILES: c1ccc2c(-c3c4ccccc4c(-c4c5ccccc5c(-c5cccc6ccccc56)c5ccccc45)c4ccccc34)cccc2c1]

In this example, the HOMO energy level of the component A is −5.92 eV, and the HOMO energy level of the component B is −5.94 eV.

The host material of the light emitting layer in embodiment 1 is a mixture of the component A and the component B, the host material of the light emitting layer in comparative example 1 is the single component A, and the host material of the light emitting layer in comparative example 2 is the single component B. The other film layers and materials of the devices in embodiment 1, comparative example 1, and comparative example 2 are the same. The organic functional layers (the film layers between the anode and cathode) of the devices in comparative example 1, comparative example 2, and embodiment 1 each adopt the structure of HIL/HTL/EBL/Host:Dopant/HBL/ETL/EIL. The comparison results of performances in current efficiency, service life, and voltage of the devices in comparative example 1, comparative example 2, and embodiment 1 are as shown in Table 1.

TABLE 1

| | Host material of | Current | Service | |
|---|---|---|---|---|
| | light emitting layer | efficiency | life | Voltage |
| Comparative | A | 100% | 100% | 100% |
| example 1 | | | | |
| Comparative | B | 99% | 102% | 98% |
| example 2 | | | | |
| Embodiment 1 | A + B | 110% | 115% | 95% |

In Table 1, the device performance data in comparative example 2 and embodiment 1 is obtained by comparison with reference to the device performance data in comparative example 1. It can be seen from Table 1 that, the performance in voltage of the device in embodiment 1 is approximately equal to the performances in voltage of the devices in comparative example 1 and comparative example 2, and the performances in current efficiency and service life of the device in embodiment 1 are respectively better than those of the devices in comparative example 1 and comparative example 2. Therefore, the overall performance of the device in embodiment 1 is better than those of the devices in comparative example 1 and comparative example 2.

In some exemplary embodiments, the component A has the following structural formula:

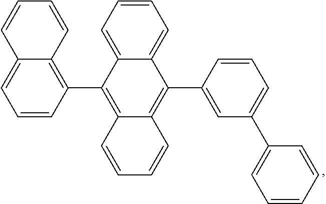 [SMILES: c1ccc(-c2cccc(-c3c4ccccc4c(-c4cccc5ccccc45)c4ccccc34)c2)cc1]

and the component B has the following structural formula:

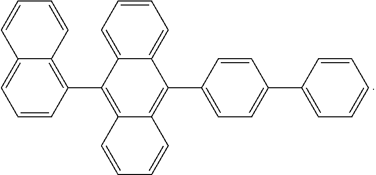 [SMILES: c1ccc(-c2ccc(-c3c4ccccc4c(-c4cccc5ccccc45)c4ccccc34)cc2)cc1]

In this example, the HOMO energy level of the component A is −5.90 eV, and the HOMO energy level of the component B is −5.91 eV.

The host material of the light emitting layer in embodiment 2 is a mixture of the component A and the component B, the host material of the light emitting layer in comparative example 1 is the single component A, and the host material of the light emitting layer in comparative example 2 is the single component B. The other film layers and materials of the devices in embodiment 2, comparative example 1, and comparative example 2 are the same. The organic functional layers of the devices in comparative example 1, comparative example 2, and embodiment 2 each adopt the structure of HIL/HTL/EBL/Host:Dopant/HBL/ETL/EIL. The comparison results of performances in current efficiency, service life, and voltage of the devices in comparative example 1, comparative example 2, and embodiment 2 are as shown in Table 2.

TABLE 2

| | Host material of | Current | Service | |
|---|---|---|---|---|
| | light emitting layer | efficiency | life | Voltage |
| Comparative | A | 100% | 100% | 100% |
| example 1 | | | | |
| Comparative | B | 105% | 98% | 98% |
| example 2 | | | | |
| Embodiment 2 | A + B | 112% | 102% | 95% |

In Table 2, the device performance data in comparative example 2 and embodiment 2 is obtained by comparison with reference to the device performance data in comparative example 1. It can be seen from Table 2 that, the performances in service life and voltage of the device in embodiment 2 are approximately equal to those of the devices in comparative example 1 and comparative example 2, and the performance in current efficiency of the device in embodiment 2 is better than those of the devices in comparative example 1 and comparative example 2. Therefore, the overall performance of the device in embodiment 2 is better than those of the devices in comparative example 1 and comparative example 2.

In some exemplary embodiments, the component A has the following structural formula:

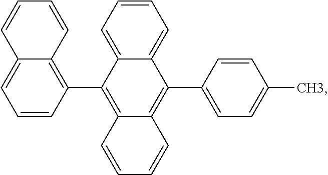 [SMILES: Cc1ccc(-c2c3ccccc3c(-c3cccc4ccccc34)c3ccccc23)cc1]

and the component B has the following structural formula:

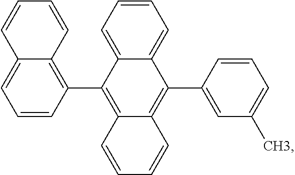 [SMILES: Cc1cccc(-c2c3ccccc3c(-c3cccc4ccccc34)c3ccccc23)c1]

In this example, the HOMO energy level of the component A is −5.8 eV, and the HOMO energy level of the component B is −5.88 eV.

The host material of the light emitting layer in example 3 is a mixture of the component A and the component B, the host material of the light emitting layer in comparative example 1 is the single component A, and the host material of the light emitting layer in comparative example 2 is the single component B. The other film layers and materials of the devices in embodiment 3, comparative example 1, and comparative example 2 are the same. The organic functional layers of the devices in comparative example 1, comparative example 2, and embodiment 3 each adopt the structure of HIL/HTL/EBL/Host:Dopant/HBL/ETL/EIL. The comparison results of performances in current efficiency, service life, and voltage of the devices in comparative example 1, comparative example 2, and embodiment 3 are as shown in Table 3.

TABLE 3

| | Host material of | Current | Service | |
|---|---|---|---|---|
| | light emitting layer | efficiency | life | Voltage |
| Comparative | A | 100% | 100% | 100% |
| example 1 | | | | |
| Comparative | B | 108% | 110% | 101% |
| example 2 | | | | |
| Embodiment 3 | A + B | 115% | 125% | 102% |

In Table 3, the device performance data in comparative example 2 and embodiment 3 is obtained by comparison with reference to the device performance data in comparative example 1. It can be seen from Table 3 that, the performance in voltage of the device in embodiment 3 is approximately equal to those of the devices in comparative example 1 and comparative example 2, and the performances in current efficiency and service life of the device in embodiment 3 are better than those of the devices in comparative example 1 and comparative example 2. Therefore, the overall performance of the device in embodiment 3 is better than those of the devices in comparative example 1 and comparative example 2.

An embodiment of the present disclosure further provides a display substrate including the electroluminescent device according to any one of the above embodiments.

In some exemplary embodiments, the display substrate may include a first sub-pixel P1 emitting first color light, a second sub-pixel P2 emitting second color light, and a third sub-pixel P3 emitting third color light. The first sub-pixel P1, the second sub-pixel P2, and the third sub-pixel P3 may be configured to emit red light, green light, and blue light, respectively. The third sub-pixel P3 includes the electroluminescent device according to any one of the above embodiments.

An embodiment of the present disclosure further provides a display apparatus including the electroluminescent device according to any one of the above embodiments. The display apparatus may be any product or component with a display function, such as a mobile phone, a tablet computer, a TV, a monitor, a notebook computer, a digital photo frame, a navigator, a vehicle-mounted display, a smart watch, or a smart bracelet.

Those skilled in the art should understand that modifications or equivalent replacements may be made to the technical solutions of the present disclosure without departing from the spirit and scope of the technical solution of the present disclosure, which, however, should be all included in the scope of the claims of the present application.

What is claimed is:

1. An electroluminescent device, comprising an anode, a cathode, and a light emitting layer disposed between the anode and the cathode, wherein the light emitting layer comprises a host material and a dopant material; and the host material comprises a component A and a component B;
the component A and the component B have the following general structural formula: 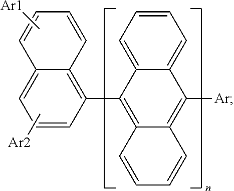
wherein n is a positive integer greater than or equal to 1;
Ar is any one of the following structures: 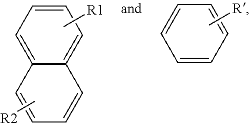
where R1, R2, and R′ are independently selected from a hydrogen atom, a halogen atom, a cyano group, a substituted or unsubstituted alkyl group, a substituted or unsubstituted alkenyl group, a substituted or unsubstituted alkynyl group, a substituted or unsubstituted alkoxy group, a substituted or unsubstituted aryl group, a substituted or unsubstituted amino group, and a substituted or unsubstituted heterocyclic group;
Ar1 and Ar2 are independently selected from a hydrogen atom, a halogen atom, a cyano group, a substituted or unsubstituted alkyl group, a substituted or unsubstituted alkenyl group, a substituted or unsubstituted alkynyl group, a substituted or unsubstituted alkoxy group, a substituted or unsubstituted aryl group, a substituted or unsubstituted amino group, and a substituted or unsubstituted heterocyclic group.

2. The electroluminescent device according to claim 1, wherein the component A and the component B are isomers of each other.

3. The electroluminescent device according to claim 1, wherein a ratio of a mass of the component A to a total mass of the component A and the component B is a, 1%≤a<100%; and
the component A and the component B satisfy: |HOMO_{A-host}|≤|HOMO_{B-host}|, where HOMO_{A-host} is a highest occupied molecular orbital energy level of the component A, and HOMO_{B-host} is a highest occupied molecular orbital energy level of the component B.

4. The electroluminescent device according to claim 1, wherein the dopant material, the component A, and the component B satisfy: |HOMO_{dopant}|≤|HOMO_{A-host}|≤|HOMO_{B-host}|; and
where HOMO_{dopant} is a highest occupied molecular orbital energy level of the dopant material, HOMO_{A-host} is a highest occupied molecular orbital energy level of the component A, and HOMO_{B-host} is a highest occupied molecular orbital energy level of the component B.

5. The electroluminescent device according to claim 1, further comprising an electron block layer disposed between the anode and the light emitting layer, wherein a material of the electron block layer, the component A, and the component B satisfy:
0<|HOMO_{A-host}−HOMO_{EBL}|≤0.3 eV, 0<|HOMO_{B-host}−HOMO_{EBL}|≤0.3 eV, and |HOMO_{EBL}|<|HOMO_{A-host}|≤|HOMO_{B-host}|;
where HOMO_{EBL} is a highest occupied molecular orbital energy level of the material of the electron block layer, HOMO_{A-host} is a highest occupied molecular orbital energy level of the component A, and HOMO_{B-host} is a highest occupied molecular orbital energy level of the component B.

6. The electroluminescent device according to claim 1, wherein the host material consists of the component A and the component B.

7. The electroluminescent device according to claim 1, wherein the component A has the following structural formula: 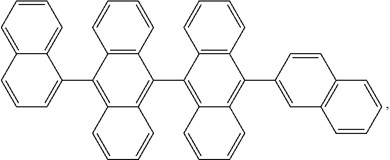 [SMILES: c1ccc2cc(-c3c4ccccc4c(-c4c5ccccc5c(-c5cccc6ccccc56)c5ccccc45)c4ccccc34)ccc2c1]
and
the component B has the following structural formula:

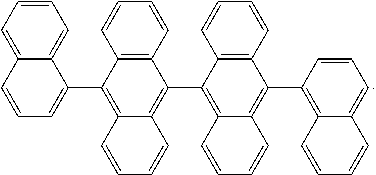 [SMILES: c1ccc2c(-c3c4ccccc4c(-c4c5ccccc5c(-c5cccc6ccccc56)c5ccccc45)c4ccccc34)cccc2c1]

8. The electroluminescent device according to claim 1, wherein the component A has the following structural formula: 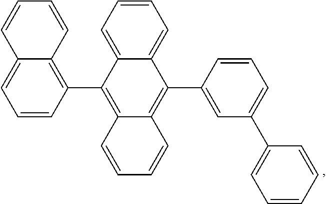 [SMILES: c1ccc(-c2cccc(-c3c4ccccc4c(-c4cccc5ccccc45)c4ccccc34)c2)cc1]
and
the component B has the following structural formula:

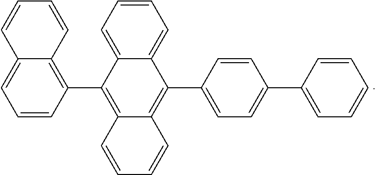 [SMILES: c1ccc(-c2ccc(-c3c4ccccc4c(-c4cccc5ccccc45)c4ccccc34)cc2)cc1]

9. The electroluminescent device according to claim 1, wherein the component A has the following structural formula: 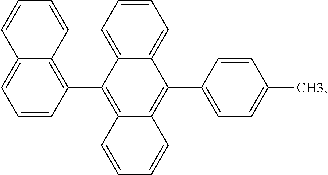 [SMILES: Cc1ccc(-c2c3ccccc3c(-c3cccc4ccccc34)c3ccccc23)cc1]
and
the component B has the following structural formula:

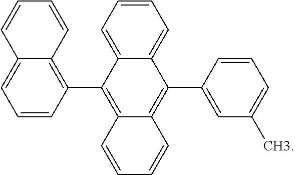 [SMILES: Cc1cccc(-c2c3ccccc3c(-c3cccc4ccccc34)c3ccccc23)c1]

10. The electroluminescent device according to claim 1, further comprising a hole injection layer, a hole transport layer, and an electron block layer sequentially stacked between the anode and the light emitting layer, and a hole block layer, an electron transport layer, and an electron injection layer sequentially stacked between the light emitting layer and the cathode.

11. A display apparatus, comprising the electroluminescent device according to claim 1.

12. The electroluminescent device according to claim 3, wherein the component A has the following structural formula: 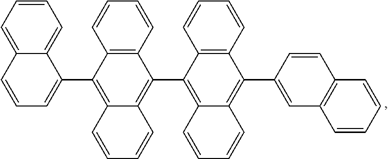 [SMILES: c1ccc2cc(-c3c4ccccc4c(-c4c5ccccc5c(-c5cccc6ccccc56)c5ccccc45)c4ccccc34)ccc2c1]
and
the component B has the following structural formula:

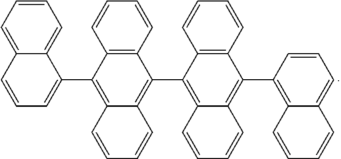 [SMILES: c1ccc2c(-c3c4ccccc4c(-c4c5ccccc5c(-c5cccc6ccccc56)c5ccccc45)c4ccccc34)cccc2c1]

13. The electroluminescent device according to claim 4, wherein the component A has the following structural formula: 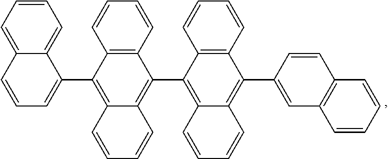 [SMILES: c1ccc2cc(-c3c4ccccc4c(-c4c5ccccc5c(-c5cccc6ccccc56)c5ccccc45)c4ccccc34)ccc2c1]
and
the component B has the following structural formula:

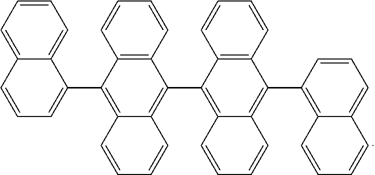 [SMILES: c1ccc2c(-c3c4ccccc4c(-c4c5ccccc5c(-c5cccc6ccccc56)c5ccccc45)c4ccccc34)cccc2c1]

14. The electroluminescent device according to claim 5, wherein the component A has the following structural formula: 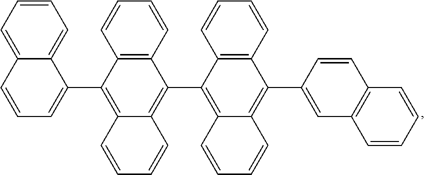 [SMILES: c1ccc2cc(-c3c4ccccc4c(-c4c5ccccc5c(-c5cccc6ccccc56)c5ccccc45)c4ccccc34)ccc2c1]
and
the component B has the following structural formula:

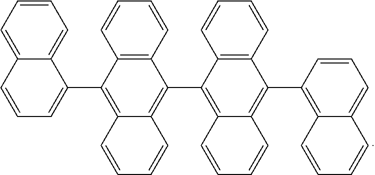 [SMILES: c1ccc2c(-c3c4ccccc4c(-c4c5ccccc5c(-c5cccc6ccccc56)c5ccccc45)c4ccccc34)cccc2c1]

15. The electroluminescent device according to claim 3, wherein the component A has the following structural formula: 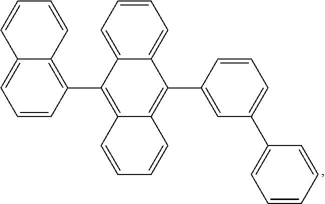 [SMILES: c1ccc(-c2cccc(-c3c4ccccc4c(-c4cccc5ccccc45)c4ccccc34)c2)cc1]
and
the component B has the following structural formula:

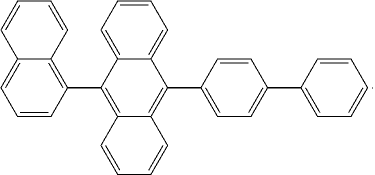 [SMILES: c1ccc(-c2ccc(-c3c4ccccc4c(-c4cccc5ccccc45)c4ccccc34)cc2)cc1]

16. The electroluminescent device according to claim 4, wherein the component A has the following structural formula: 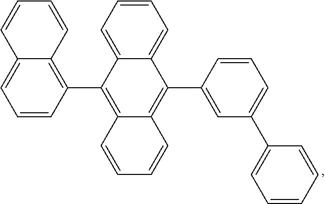 [SMILES: c1ccc(-c2cccc(-c3c4ccccc4c(-c4cccc5ccccc45)c4ccccc34)c2)cc1]
and
the component B has the following structural formula:

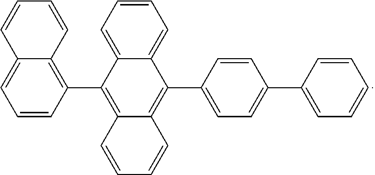 [SMILES: c1ccc(-c2ccc(-c3c4ccccc4c(-c4cccc5ccccc45)c4ccccc34)cc2)cc1]

17. The electroluminescent device according to claim 5, wherein the component A has the following structural formula: 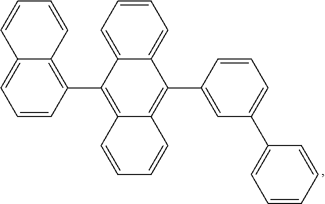 [SMILES: c1ccc(-c2cccc(-c3c4ccccc4c(-c4cccc5ccccc45)c4ccccc34)c2)cc1]
and
the component B has the following structural formula:

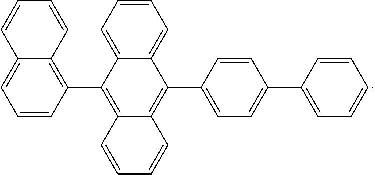 [SMILES: c1ccc(-c2ccc(-c3c4ccccc4c(-c4cccc5ccccc45)c4ccccc34)cc2)cc1]

18. The electroluminescent device according to claim 3, wherein the component A has the following structural formula: 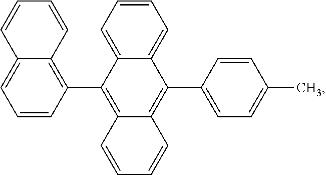 [SMILES: Cc1ccc(-c2c3ccccc3c(-c3cccc4ccccc34)c3ccccc23)cc1]
and
the component B has the following structural formula:

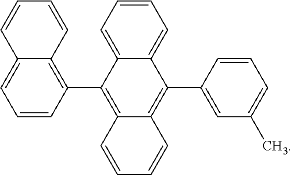 [SMILES: Cc1cccc(-c2c3ccccc3c(-c3cccc4ccccc34)c3ccccc23)c1]

19. The electroluminescent device according to claim 4, wherein the component A has the following structural formula: 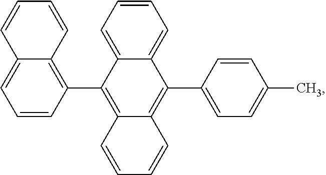 [SMILES: Cc1ccc(-c2c3ccccc3c(-c3cccc4ccccc34)c3ccccc23)cc1]
and
the component B has the following structural formula:

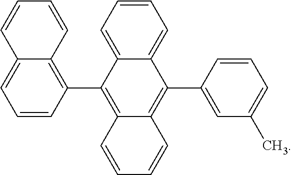 [SMILES: Cc1cccc(-c2c3ccccc3c(-c3cccc4ccccc34)c3ccccc23)c1]

20. The electroluminescent device according to claim 5, wherein the component A has the following structural formula: 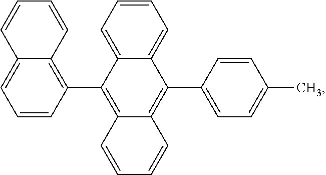 [SMILES: Cc1ccc(-c2c3ccccc3c(-c3cccc4ccccc34)c3ccccc23)cc1]
and
the component B has the following structural formula: 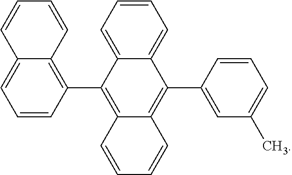 [SMILES: Cc1cccc(-c2c3ccccc3c(-c3cccc4ccccc34)c3ccccc23)c1]
